(19) United States
(12) Patent Application Publication
(10) Pub. No.: US 2024/0313506 A1
(43) Pub. Date: Sep. 19, 2024

(54) SURFACE EMITTING DEVICE

(71) Applicant: SONY GROUP CORPORATION, Tokyo (JP)

(72) Inventors: Daiji KASAHARA, Tokyo (JP); Hiroshi NAKAJIMA, Tokyo (JP); Michinori SHIOMI, Tokyo (JP); Masayuki TANAKA, Tokyo (JP); Tomomasa WATANABE, Tokyo (JP); Masashi TAKANOHASHI, Tokyo (JP); Mikihiro YOKOZEKI, Tokyo (JP)

(21) Appl. No.: 18/575,974

(22) PCT Filed: Mar. 3, 2022
(86) PCT No.: PCT/JP2022/009160

§ 371 Date: Jan. 2, 2024

(30) Foreign Application Priority Data
Aug. 12, 2021 (JP) 2021-131686

(51) Int. Cl. H01S 5/183; H01S 5/042; H01S 5/30; H01S 5/343

(52) U.S. Cl. CPC H01S 5/18322; H01S 5/0421; H01S 5/04256; H01S 5/18369; H01S 5/18394; H01S 5/3013; H01S 5/3095; H01S 5/343

(57) ABSTRACT

A surface emitting device according to an embodiment of the present disclosure includes: a first reflective layer; a first semiconductor layer of a first conductive type, the first semiconductor layer being stacked on the first reflective layer; an active layer stacked on the first semiconductor layer; a second semiconductor layer of a second conductive type that is a conductive type opposite to the first conductive type, the second semiconductor layer being stacked on the active layer; a tunnel junction layer stacked on the second semiconductor layer; a third semiconductor layer of the first conductive type, the third semiconductor layer being stacked on the tunnel junction layer; a second reflective layer stacked on the third semiconductor layer, at a side opposite to a side of the first reflective layer; a dielectric layer formed, through non-selective oxidation, between the second semiconductor layer and the third semiconductor layer or between the third semiconductor layer and the second reflective layer, the dielectric layer having an aperture penetrating through in a thickness direction; and a fourth semiconductor layer stacked, within the aperture, on the second semiconductor layer or the third semiconductor layer and formed through selective growth of the second semiconductor layer or the third semiconductor layer.

### TECHNICAL FIELD

The present disclosure relates to a surface emitting device.

### BACKGROUND ART

In connection with a vertical cavity surface emitting laser (hereinafter, simply referred to as a “VCSEL”) mounted on an InP substrate, Patent Literatures 1 to 3 disclose a method of confining a current.

The VCSEL disclosed in Patent Literature 1 includes a tunnel junction having a mesa shape and embedded between a compound semiconductor region and a distributed bragg reflector (hereinafter, simply referred to as a “DBR”).

The VCSEL disclosed in Patent Literature 2 includes a current confining layer including AlInAs. The current confining layer includes an oxidized region formed through selective oxidation of AlInAs, and also includes an oxidized aperture that is an electrically conductive region that is not selected. In addition, in the VCSEL, a tunnel junction portion is formed to spread a current. The tunnel junction portion has an opposed semiconductor type, and hence, it is possible to improve electrical properties while reducing light absorption at a p-type layer.

In the VCSEL disclosed in Patent Literature 3, the function of the tunnel junction portion is eliminated, and a high resistance portion for narrowing the current path portion is formed. The high resistance portion is formed by introducing molecules or elements through ion implantation.

### CITATION LIST

### Patent Literature

Patent Literature 1: Japanese Unexamined Patent Application Publication No. 2008-283137
Patent Literature 2: Japanese Unexamined Patent Application Publication No. 2006-351798

Patent Literature 3: Japanese Unexamined Patent Application Publication No. 2003-324251

### SUMMARY OF THE INVENTION

In a case of the VCSEL disclosed in Patent Literature 1 above, a complicated manufacturing process is used to form the tunnel junction having the mesa shape. In addition, in a case of the VCSEL disclosed in Patent Literature 2 above, the speed of selective oxidation of AlInAs is slow, and it takes long time to manufacture the current confining layer. Furthermore, in a case of the VCSEL disclosed in Patent Literature 3 above, hydrogen ions are used to form the high resistance portion, and hence, there is room for improvement in terms of light confining.

For these reasons, a surface emitting device that makes it possible to achieve current confining and light confining with a simplified structure has been desired.

A surface emitting device according to an embodiment of the present disclosure includes: a first reflective layer: a first semiconductor layer of a first conductive type, the first semiconductor layer being stacked on the first reflective layer; an active layer stacked on the first semiconductor layer; a second semiconductor layer of a second conductive type that is a conductive type opposite to the first conductive type, the second semiconductor layer being stacked on the active layer: a tunnel junction layer stacked on the second semiconductor layer: a third semiconductor layer of the first conductive type, the third semiconductor layer being stacked on the tunnel junction layer: a second reflective layer stacked on the third semiconductor layer, at a side opposite to a side of the first reflective layer: a dielectric layer formed, through non-selective oxidation, between the second semiconductor layer and the third semiconductor layer or between the third semiconductor layer and the second reflective layer, the dielectric layer having an aperture penetrating through in a thickness direction; and a fourth semiconductor layer stacked, within the aperture, on the second semiconductor layer or the third semiconductor layer and formed through selective growth of the second semiconductor layer or the third semiconductor layer.

A surface emitting device according to an embodiment of the present disclosure includes: a first reflective layer: a first semiconductor layer; an active layer; a second semiconductor layer: a tunnel junction layer; a third semiconductor layer; and a second reflective layer. The first semiconductor layer is stacked on the first reflective layer, and has a first conductive type. The active layer is stacked on the first semiconductor layer. The second semiconductor layer is stacked on the active layer, and has a second conductive type. The tunnel junction layer is stacked on the second semiconductor layer. The third semiconductor layer is stacked on the tunnel junction layer, and has the first conductive type. The second reflective layer is stacked on the third semiconductor layer, at a side opposite to the first reflective layer side. In addition, the surface emitting device further includes a dielectric layer and a fourth semiconductor layer. The dielectric layer is formed, through non-selective oxidation, between the second semiconductor layer and the third semiconductor layer or between the third semiconductor layer and the second reflective layer, and has an aperture penetrating through in a thickness direction. The fourth semiconductor layer is stacked, within the aperture, on the second semiconductor layer or the third semiconductor layer, and is formed through selective growth of the second semiconductor layer or the third semiconductor layer.

Here, the dielectric layer functions as a current confining layer and a light confining layer. In addition, since the dielectric layer is formed through non-selective oxidation, it is possible to form the dielectric layer in a simplified manner and in a short period of time.

### BRIEF DESCRIPTION OF THE DRAWINGS

FIG. 1 is a cross-sectional view of the main components of a surface emitting device according to a first embodiment of the present disclosure.

FIG. 2 is a schematic plan view of an aperture portion of a dielectric layer of the surface emitting device illustrated in FIG. 1.

FIG. 3 is a cross-sectional view of a first step used to describe a process of manufacturing the surface emitting device according to the first embodiment.

FIG. 4 is a cross-sectional view of a second step used to describe a process of manufacturing the surface emitting device.

FIG. 5 is a cross-sectional view of a third step used to describe a process of manufacturing the surface emitting device.

FIG. 6 is a cross-sectional view of a fourth step used to describe a process of manufacturing the surface emitting device.

FIG. 7 is a cross-sectional view of a fifth step used to describe a process of manufacturing the surface emitting device.

FIG. 8A is a schematic plan view corresponding to FIG. 2 and illustrating an aperture of a dielectric layer of a surface emitting device according to a first modification example of the first embodiment.

FIG. 8B is a schematic plan view corresponding to FIG. 2 and illustrating an aperture of a dielectric layer of a surface emitting device according to a second modification example of the first embodiment.

FIG. 8C is a schematic plan view corresponding to FIG. 2 and illustrating an aperture of a dielectric layer of a surface emitting device according to a third modification example of the first embodiment.

FIG. 9 is a cross-sectional view corresponding to FIG. 1 and illustrating the main components of a surface emitting device according to a second embodiment of the present disclosure.

FIG. 10 is a cross-sectional view corresponding to FIG. 1 and illustrating the main components of a surface emitting device according to a third embodiment of the present disclosure.

FIG. 11 is a cross-sectional view corresponding to FIG. 1 and illustrating the main components of a surface emitting device according to a fourth embodiment of the present disclosure.

FIG. 12 is a cross-sectional view corresponding to FIG. 1 and illustrating the main components of a surface emitting device according to a fifth embodiment of the present disclosure.

FIG. 13 is an enlarged cross-sectional view of the main components of the dielectric layer of the surface emitting device illustrated in FIG. 12.

FIG. 14 is a schematic plan view corresponding to FIG. 2 and illustrating an aperture portion of the dielectric layer illustrated in FIG. 13.

FIG. 15A is a schematic plan view corresponding to FIG. 14 and illustrating an aperture of a dielectric layer of a surface emitting device according to a first modification example of the fifth embodiment.

FIG. 15B is a schematic plan view corresponding to FIG. 14 and illustrating an aperture of a dielectric layer of a surface emitting device according to a second modification example of the fifth embodiment.

FIG. 15C is a schematic plan view corresponding to FIG. 14 and illustrating an aperture of a dielectric layer of a surface emitting device according to a third modification example of the fifth embodiment.

FIG. 16 is an enlarged cross-sectional view corresponding to FIG. 13 and illustrating the main components of a dielectric layer of a surface emitting device according to a sixth embodiment of the present disclosure.

FIG. 17 is a cross-sectional view corresponding to FIG. 1 and illustrating the main components of a surface emitting device according to a seventh embodiment of the present disclosure.

FIG. 18 is a cross-sectional view corresponding to FIG. 1 and illustrating the main components of a surface emitting device according to an eighth embodiment of the present disclosure.

FIG. 19 is a cross-sectional view corresponding to FIG. 1 and illustrating the main components of a surface emitting device according to a ninth embodiment of the present disclosure.

FIG. 20 is a cross-sectional view corresponding to FIG. 1 and illustrating the main components of a surface emitting device according to a tenth embodiment of the present disclosure.

FIG. 21 is a cross-sectional view corresponding to FIG. 1 and illustrating the main components of a surface emitting device according to an eleventh embodiment of the present disclosure.

FIG. 22 is a cross-sectional view corresponding to FIG. 1 and illustrating the main components of a surface emitting device according to a twelfth embodiment of the present disclosure.

FIG. 23 is a cross-sectional view corresponding to FIG. 1 and illustrating the main components of a surface emitting device according to a thirteenth embodiment of the present disclosure.

FIG. 24 is a cross-sectional view corresponding to FIG. 1 and illustrating the main components of a surface emitting device according to a fourteenth embodiment of the present disclosure.

### MODES FOR CARRYING OUT THE INVENTION

Below, embodiments according to the present disclosure will be described in detail with reference to the drawings. Note that description will be given in the following order.

### 1. First Embodiment

The first embodiment describes an example in which the present technology is applied to a surface emitting device. Here, description will be made of a basic structure of the surface emitting device and a manufacturing process.

### 2. Second Embodiment

The second embodiment describes an example in which the present technology is applied, and the structure of a tunnel junction layer of the surface emitting device according to the first embodiment is modified.

### 3. Third Embodiment

The third embodiment describes another example in which the present technology is applied, and the structure of the tunnel junction layer of the surface emitting device according to the first embodiment is modified.

### 4. Fourth Embodiment

The fourth embodiment describes another example in which the present technology is applied, and a second reflective layer of the surface emitting device according to the first embodiment has a structure of a semiconductor DBR.

### 5. Fifth Embodiment

The fifth embodiment describes an example in which the present technology is applied, and the structure of the dielectric layer of the surface emitting device according to the first embodiment is modified.

### 6. Sixth Embodiment

The sixth embodiment describes another example in which the present technology is applied, and the structure of the dielectric layer of the surface emitting device according to the first embodiment is modified.

### 7. Seventh Embodiment

The seventh embodiment describes an example in which the present technology is applied, and a first reflective layer of the surface emitting device according to the first embodiment is structured so as to be bonded to a foreign substrate DBR.

### 8. Eighth Embodiment

The eighth embodiment describes an example in which the present technology is applied, and the first reflective layer of the surface emitting device according to the first embodiment is configured as a lens-type reflective layer.

### 9. Ninth Embodiment

The ninth embodiment describes an example in which the present technology is applied, and the first reflective layer of the surface emitting device according to the first embodiment is structured such that a foreign substrate and a dielectric body DBR are bonded together.

### 10. Tenth Embodiment

The tenth embodiment describes an example in which the present technology is applied, and the first reflective layer of the surface emitting device according to the first embodiment is structured such that a foreign substrate and a lens-type reflective layer are bonded together.

### 11. Eleventh Embodiment

The eleventh embodiment describes an example in which the present technology is applied, and the second reflective layer of the surface emitting device according to the first embodiment is configured as a lens-type reflective layer.

### 12. Twelfth Embodiment

The twelfth embodiment describes an example in which the present technology is applied, and the second reflective layer of the surface emitting device according to the first embodiment is structured such that the dielectric body DBR and a lens-type reflective layer are combined together.

### 13. Thirteenth Embodiment

The thirteenth embodiment describes an example in which the present technology is applied, and the surface emitting device according to the first embodiment has a back-side emitting structure.

### 14. Fourteenth Embodiment

The fourteenth embodiment describes another example in which the present technology is applied, and the surface emitting device according to the first embodiment has a back-side emitting structure.

### 15. Other Embodiments

### 1. First Embodiment

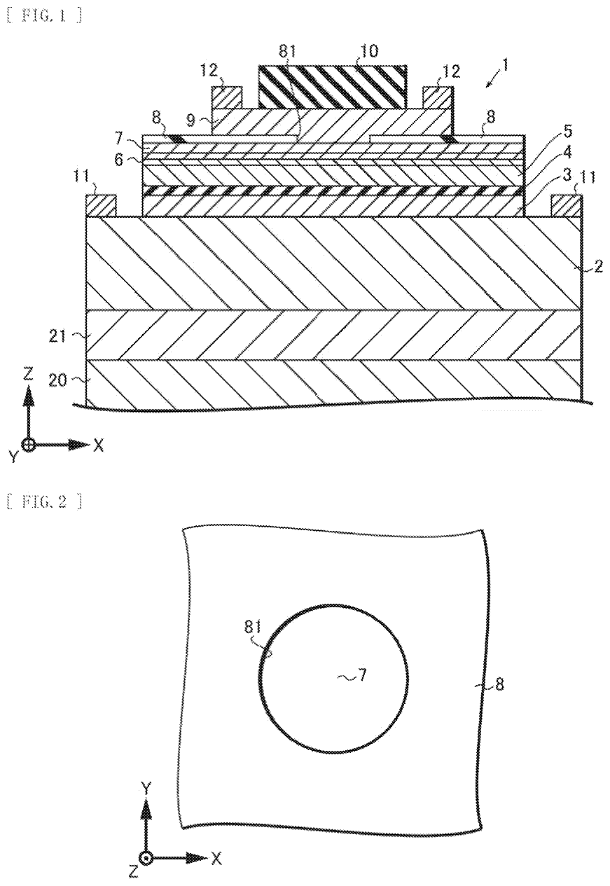

A surface emitting device 1 according to the first embodiment of the present disclosure will be described with reference to FIGS. 1 to 8.

Here, in the drawings, the arrowed X direction is illustrated on an as-necessary basis, and indicates one planar direction of the surface emitting device 1 placed on a plane, for the purpose of convenience. The arrowed Y direction indicates the other one planar direction perpendicular to the arrowed X direction. In addition, the arrowed Z direction indicates an upward direction perpendicular to the arrowed X direction and the arrowed Y direction. In other words, the arrowed X direction, the arrowed Y direction, and the arrowed Z direction precisely correspond to the X axis direction, the Y axis direction, and the Z axis direction, respectively, in a three-dimensional coordinate system.

Note that each of these directions is given with the aim of facilitating understanding of explanation, and is not provided for the purpose of limiting the directions in the present technology.

### [Configuration of Surface Emitting Device 1]

### (1) Entire Schematic Configuration of Surface Emitting Device 1

FIG. 1 illustrates one example of the configuration, in longitudinal cross section, of the surface emitting device 1.

The surface emitting device 1 according to the first embodiment is configured as a VCSEL (Vertical Cavity Surface Emitting Laser). As main constituent elements, the surface emitting device 1 includes a first reflective layer 2, a first semiconductor layer 3, an active layer 4, a second semiconductor layer 5, a tunnel junction layer 6, a third semiconductor layer 7, and a second reflective layer 10. In addition, the surface emitting device 1 further includes a dielectric layer 8 and a fourth semiconductor layer 9 as main constituent elements.

Furthermore, the surface emitting device 1 further includes a first electrode 11 and a second electrode 12.

### (2) Configuration of First Reflective Layer 2

The first reflective layer 2 is stacked on a substrate 20 with a buffer layer 21 being interposed therebetween.

The substrate 20 is used as an epitaxial growth substrate. For example, n-type InP is used for the substrate 20. S is used as an n-type impurity.

The buffer layer 21 is used to form a step structure and a terrace having high evenness. Here, for example, n-type InP is used for the buffer layer 21. Si is used as an n-type impurity serving as a dopant. The buffer layer 21 is formed, for example, so as to have a film thickness of not less than 100 nm and not more than 500 nm. Furthermore, the density of the n-type impurity is set to 1×10¹⁸ atoms/cm³.

The first reflective layer 2 is configured as a semiconductor DBR (Distributed Bragg Reflector). The first reflective layer 2 is configured such that semiconductor layers having two or more types of different indices of refraction is alternately stacked a plurality of times.

Specifically, the first reflective layer 2 is configured by stacking semiconductor layers having at least two or more types of indices of refraction and selected from InP, AlxGay In1−x−yAs (0≤x, y≤1), and InxGa1−xAs1−yPy (0≤x, y≤1). Here, the first reflective layer 2 is formed, for example, by alternately stacking a semiconductor of n-type AlGaInAs and a semiconductor layer of n-type InP into 40 or more pairs.

For example, in the AlGaInAs, Si is used as an n-type impurity, and the density of the n-type impurity is set, for example, to 1×10¹⁸ atoms/cm³. In addition, by using a resonant wavelength λ and a refraction index n_{AlGaInAs} of the AlGaInAs, the film is formed so as to have a film thickness of λ/4n_{AlGaInAs}, for example.

For example, in the InP, Si is used as an n-type impurity, and the density of the n-type impurity is set, for example, to 1×10¹⁸ atoms/cm³. In addition, by using a resonant wavelength λ and a refraction index n_{InP} of the InP, the film is formed so as to have a film thickness of λ/4n_{InP}, for example.

### (3) Configuration of First Semiconductor Layer 3

The first semiconductor layer 3 is stacked on the first reflective layer 2 with a clad layer being interposed therebetween.

Here, an n-type InP is used for the clad layer, for example. For example, in the InP, Si is used as an n-type impurity, and the density of the n-type impurity is set, for example, to 1×10¹⁸ atoms/cm³. In addition, the InP is formed so as to have a thickness of not less than 320 nm and not more than 330 nm, for example.

The first semiconductor layer 3 is used as a guide layer or a spacer layer. The first semiconductor layer 3 includes a non-doped AlInAs and a non-doped AlGaInAs stacked on the AlInAs. The AlInAs is formed so as to have a thickness of not less than 50 nm and not more than 70 nm, for example. The AlGaInAs is formed so as to have a thickness of not less than 50 nm and not more than 70 nm, for example.

### (4) Configuration of Active Layer 4

The active layer 4 has a structure in which a barrier layer and a quantum well layer are alternately stacked a plurality of times, and is stacked on the first semiconductor layer 3.

For example, a non-doped AlGaInAs is used for the barrier layer. For example, five layers of the AlGaInAs are formed, and each of the layers of the AlGaInAs is formed so as to have a thickness of not less than 8 nm and not more than 10 nm, for example.

The quantum well layer includes at least one element selected from Al, Ga, and In of group III elements, and at least one element selected from As, P, and N of group V elements. Here, the quantum well layer includes the non-doped AlGaInAs as a main component. For example, four layers of the AlGaInAs is formed, and each of the layers of the AlGaInAs is formed so as to have a thickness of not less than 4 nm and not more than 7 nm, for example.

In addition, it may be possible to use a quantum wire or a quantum dot, instead of the quantum well layer. Furthermore, in the first embodiment, the active layer 4 is configured as a strain-compensated quantum well, and is formed at the position of an anti-node of the standing wave within a cavity.

### (5) Configuration of Second Semiconductor Layer 5

The second semiconductor layer 5 is stacked on the active layer 4.

The second semiconductor layer 5 is used as a guide layer or a spacer layer. The second semiconductor layer 5 includes a non-doped AlGaInAs, a non-doped AlInAs stacked on the AlGaInAs, and a p-type AlGaInAs stacked on the AlInAs.

The non-doped AlGaInAs is formed so as to have a thickness of not less than 50 nm and not more than 70 nm, for example. The non-doped AlInAs is formed so as to have a thickness of not less than 50 nm and not more than 70 nm, for example.

In the p-type AlGaInAs, Mg is used as a p-type impurity, and the density of the p-type impurity is set to 1×10¹⁸ atoms/cm³, for example. In addition, the p-type AlGaInAs is formed so as to have a thickness of not less than 160 nm and not more than 180 nm, for example.

### (6) Configuration of Tunnel Junction Layer 6

The tunnel junction layer 6 is stacked on the second semiconductor layer 5. Here, the tunnel junction layer 6 includes a p-type AlInAs, and an n-type InP stacked on the AlInAs.

In the AlInAs, C is used as a p-type impurity, and the density of the p-type impurity is set to not less than 1×10¹⁹ atoms/cm³, for example. In addition, the AlInAs is formed so as to have a thickness of not less than 10 nm and not more than 30 nm, for example.

In the InP, Si is used as an n-type impurity, and the density of the n-type impurity is set to not less than 1×10¹⁹ atoms/cm³, for example. In addition, the InP is formed so as to have a thickness of not less than 10 nm and not more than 30 nm, for example.

### (7) Configuration of Third Semiconductor Layer 7

The third semiconductor layer 7 is stacked on the tunnel junction layer 6. The third semiconductor layer 7 is used as a clad layer or a cap layer. Here, the third semiconductor layer 7 includes, for example, an n-type InP. For example, in the InP, Si is used as an n-type impurity, and the density of the n-type impurity is set, for example, to 1×10¹⁸ atoms/cm³. In addition, the InP is formed so as to have a thickness of not less than 10 nm and not more than 40 nm, for example.

(8) Configuration of Dielectric layer 8

In the surface emitting device 1 according to the first embodiment, the dielectric layer 8 is stacked on the third semiconductor layer 7. The dielectric layer 8 has an aperture 81 extending in a thickness direction (arrowed Z direction) of the dielectric layer 8. The dielectric layer 8 suppresses spreading of a current and light in a lateral direction, and a current and light pass through the inside of the aperture 81. That is, the dielectric layer 8 functions as a current confining layer and a light confining layer.

FIG. 2 illustrates a plane of the dielectric layer 8 as viewed from the arrowed Z direction (hereinafter, simply referred to as “in plan view”). Here, the aperture 81 of the dielectric layer 8 is formed so as to have a circular shape.

Returned to FIG. 1, the dielectric layer 8 is formed through non-selective oxidation. That is, the dielectric layer 8 does not use an oxidized layer formed through selective oxidation of AlInAs that is slow in oxidation speed. Specifically, the dielectric layer 8 includes a deposited film formed by taking a compound semiconductor out from a furnace for crystal growth and performing a deposition method. Detailed description will be made in a manufacturing method.

The dielectric layer 8 includes a material containing, as a main component, at least one selected from SiOx, SiNx, AIOx, AlNx, BNx, GaOx, GaNx, HfOx, GdOx, BeOx, MgOx, CaOx, InOx, GeOx, WOx, TaOx, TiOx, NbOx, VOX, ScOx, CrOx, FeOx, CoOx, NiOx, CuOx, ZnOx, ZrOx, MoOx, TeOx, BiOx, SrOx, YOx, ScOx, MnOx, EuOx, LaOx, NdOx, DyOx, CeOx, YbOx, and ErOx, where x is greater than 0 (0<x).

For example, in a case where SiO2 is selected for the dielectric layer 8, the dielectric layer 8 is formed so as to have a thickness of not less than 1 nm and not more than 500 nm, for example.

In addition, the dielectric layer 8 may include a material containing, as a component, at least one selected from LiF, KF, CaF2, GaF3, ZnF2, CoF2, AlF2, PbF2, InF3, CrF3, FeF3, NiF2, CuF2, BiF3, MnF2, SnF4, BaF2, ZrF4, AlF3, LaF, MnF2, SrF2, MgS, ZnS, ZnSe, MgTe, ZnTe, GeS2, SiS2, and SiC.

### (9) Configuration of Fourth Semiconductor Layer 9

The fourth semiconductor layer 9 is stacked, within the aperture 81, on the third semiconductor layer 7. In the first embodiment, the fourth semiconductor layer 9 is formed so as to have a thickness thicker than the dielectric layer 8, and is formed at the aperture 81 and also over the dielectric layer 8 outside of the aperture 81. The fourth semiconductor layer 9 is formed through selective epitaxial growth (epitaxial regrowth) of the third semiconductor layer 7 exposed within the aperture 81. The fourth semiconductor layer 9 is used as a clad layer or a cap layer.

The fourth semiconductor layer 9 includes, for example, an n-type InP. For example, in the InP, Si is used as an n-type impurity, and the density of the n-type impurity is set, for example, to 1×10¹⁸ atoms/cm³. In addition, the InP is formed so as to have a thickness of not less than 2000 nm and not more than 2100 nm, for example.

### (10) Configuration of Second Reflective Layer 10

The second reflective layer 10 is stacked on the fourth semiconductor layer 9. The second reflective layer 10 is configured as a DBR, as with the first reflective layer 2. In addition, the second reflective layer 10 is configured as a reflective layer at a light outputting side.

The second reflective layer 10 is configured such that materials having two or more types of different indices of refraction are alternately stacked a plurality of times. Specifically, in the first embodiment, the second reflective layer 10 is formed, for example, by alternately stacking SiO2 and Ta2O5 into seven or more pairs. In addition, by using a resonant wavelength A and a refraction index n_{SiO2} of the SiO2, the SiO2 is formed so as to have a thickness of λ/4n_{SiO2}, for example. In addition, by using a resonant wavelength λ and a refraction index n_{Ta2O5} of the Ta2O5, the Ta2O5 is formed so as to have a thickness of λ/4n_{Ta2O5}. The second reflective layer 10 includes a dielectric body, and hence, is a dielectric body DBR.

### (11) Configurations of First Electrode 11 and Second Electrode 12

A peripheral edge portion of the first reflective layer 2 extends in a planar direction (here, in at least the arrowed X direction) further than a peripheral edge portion of the first semiconductor layer 3. The first electrode 11 is stacked on this peripheral edge portion of the first reflective layer 2 or the clad layer. The first electrode 11 is electrically coupled to the first semiconductor layer 3 with the first reflective layer 2 or the clad layer being interposed therebetween.

A peripheral edge portion of the fourth semiconductor layer 9 extends in a planar direction (here, in at least the arrowed X direction) further than a peripheral edge portion of the second reflective layer 10, as with the peripheral edge portion of the first reflective layer 2. The second electrode 12 is stacked on this peripheral edge portion of the fourth semiconductor layer 9. The second electrode 12 is electrically coupled to the third semiconductor layer 7 with the fourth semiconductor layer 9 being interposed therebetween.

### [Method of Manufacturing Surface Emitting Device 1]

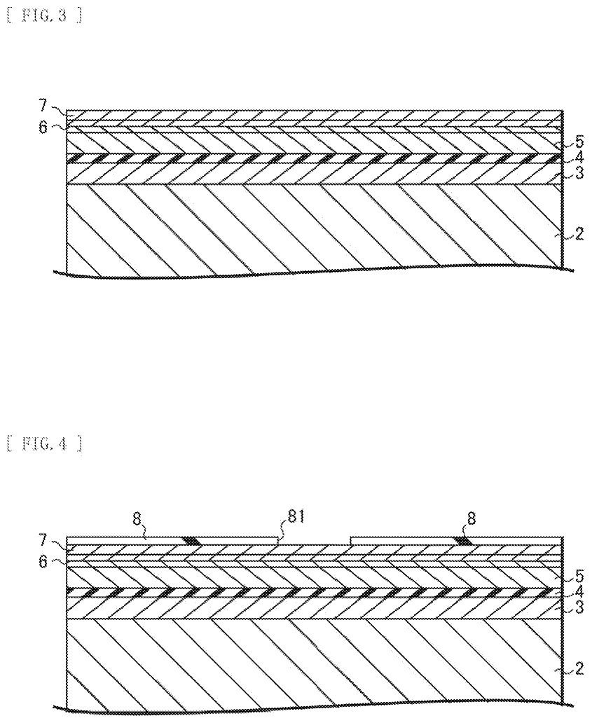

FIGS. 3 to 7 illustrate individual steps used to describe a method of manufacturing the surface emitting device 1 according to the first embodiment.

First, in the method of manufacturing the surface emitting device 1, the buffer layer 21 is formed on the substrate 20 (see FIG. 1). As described above, for example, a compound semiconductor of an n-type InP is used for the substrate 20.

For example, an n-type InP is used for the buffer layer 21. The buffer layer 21 is formed using a MOCVD (metal organic chemical vapor deposition) method or a MBE (molecular beam epitaxy) method.

The first reflective layer 2 is formed on the buffer layer 21 (see FIG. 3). The first reflective layer 2 is formed, for example, by alternately stacking an n-type AlGaInAs and an n-type InP a plurality of times. The first reflective layer 2 is formed using an MOCVD method or a MBE method.

The first semiconductor layer 3 is formed on the first reflective layer 2 with a clad layer being interposed therebetween (see FIG. 3). The clad layer includes, for example, an n-type InP. The first semiconductor layer 3 is formed, for example, by sequentially stacking a non-doped AlInAs and a non-doped AlGaInAs. The clad layer and the first semiconductor layer 3 are each formed using an MOCVD method or a MBE method.

The active layer 4 in which a barrier layer and a quantum well layer are alternately stacked a plurality of times is formed on the first semiconductor layer 3 (see FIG. 3). The barrier layer includes, for example, a non-doped AlGaInAs. The quantum well layer includes, for example, a non-doped AlGaInAs as a main component. The active layer 4 is formed using an MOCVD method or a MBE method.

The second semiconductor layer 5 is formed on the active layer 4 (see FIG. 3). The second semiconductor layer 5 is formed by sequentially stacking a non-doped AlGaInAs, a non-doped AlInAs, and a p-type AlGaInAs. Each of them of the second semiconductor layer 5 is formed using a MOCVD or a MBE method.

The tunnel junction layer 6 is formed on the second semiconductor layer 5 (see FIG. 3). The tunnel junction layer 6 is formed, for example, by sequentially stacking a p-type AlInAs and an n-type InP. The tunnel junction layer 6 is formed using a MOCVD or a MBE method.

As illustrated in FIG. 3, the third semiconductor layer 7 is formed on the tunnel junction layer 6. The third semiconductor layer 7 includes, for example, an n-type InP. The third semiconductor layer 7 is formed using an MOCVD method or an MBE method.

Here, processes performed from the buffer layer 21 to the third semiconductor layer 7 such as an epitaxial growth process are performed in the same furnace.

Here, the substrate 20 is taken out from the inside of the furnace to the outside of the furnace, and is transported to a film forming device. Then, with the film forming device, the dielectric layer 8 is formed on the third semiconductor layer 7 (see FIG. 4). The dielectric layer 8 is formed as a deposited film using the material described above. The dielectric layer 8 is formed, for example, using a deposition method such as a vapor deposition method, sputtering, a CVD (Chemical Vaper Deposition) method, an ALD (Atomic Layer Deposition) method, or the like, depending on the material used.

That is, the dielectric layer 8 is formed as a deposited film, and hence, is formed through non-selective oxidation, rather than being an oxidized layer formed through selective oxidation, for example.

The aperture 81 is formed in the dielectric layer 8, as illustrated in FIG. 4. The aperture 81 is formed such that a mask is formed on the dielectric layer 8 using a photo photolithography technique, and the dielectric layer 8 is selectively etched using this mask. Etching includes wet etching and drying etching such as RIE (Reactive Ion Etching). In addition, the aperture 81 may be formed using a photolithography technique using a lift-off process.

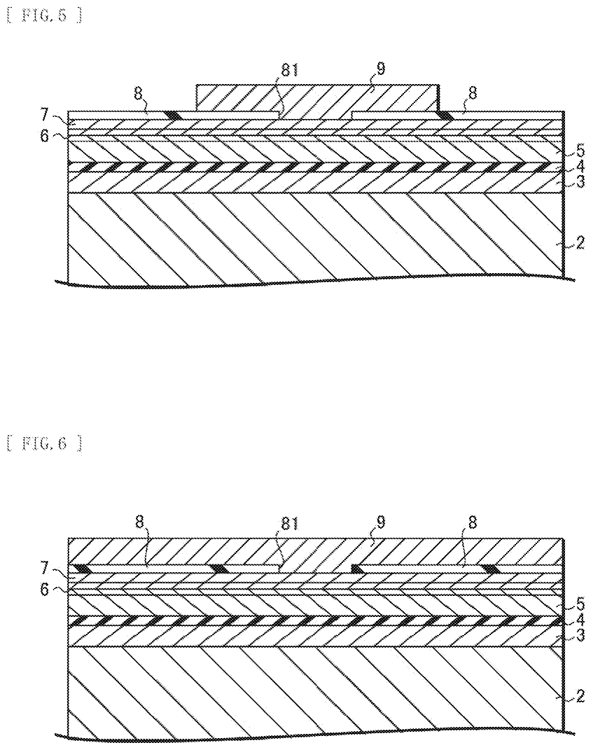

After the dielectric layer 8 is formed, the substrate 20 is transported from a deposition device into a furnace. In the furnace, the fourth semiconductor layer 9 is formed on the third semiconductor layer 7 exposed within the aperture 81 of the dielectric layer 8, as illustrated in FIG. 5. The fourth semiconductor layer 9 is formed through selective lateral-direction growth (ELO: Epitaxial Lateral Over growth) so as to have a thickness thicker than the thickness of the dielectric layer 8. In addition, as illustrated in FIG. 6, the fourth semiconductor layer 9 may be formed outside of the aperture 81 and on the entire area of the dielectric layer 8. The fourth semiconductor layer 9 includes an n-type InP formed using the third semiconductor layer 7 as a seed crystal, as with the third semiconductor layer 7, for example.

In the method of manufacturing the surface emitting device 1 according to the first embodiment, a plurality of surface emitting devices 1 is manufactured at one substrate 20. In addition, fourth semiconductor layers 9 in formation regions where adjacent surface emitting devices 1 are formed may be configured so as to be disposed close to each other or be coupled to each other.

Here, the substrate 20 is taken out from the inside of the furnace to the outside of the furnace again.

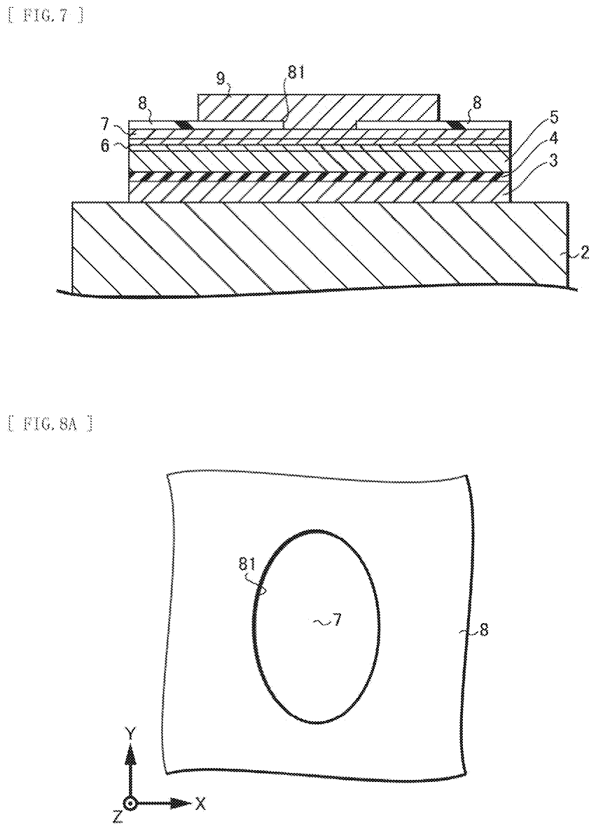

As illustrated in FIG. 7, a mask formed through a photo photolithography technique as well as an etching technique are used to pattern the first semiconductor layer 3 to the dielectric layer 8, and the fourth semiconductor layer 9 so as to each have an appropriate shape.

Wet etching or dry etching is used as the etching technique.

The first electrode 11 is formed on the peripheral edge portion of the first reflective layer 2, and the second electrode is formed on the peripheral edge portion of the fourth semiconductor layer 9 (see FIG. 1). Each of the first electrode 11 and the second electrode 12 includes a stacked film formed, for example, by sequentially stacking AuGe, Ni, and Au.

The second reflective layer 10 is formed on the fourth semiconductor layer 9 (see FIG. 1). The second reflective layer 10 is formed such that SiO2 and Ta2O5 are alternately stacked a plurality of times. The second reflective layer 10 is formed using a deposition method selected from sputtering, the CVD method, the ALD method, or the like described above.

Next, an element separation process is performed. In the element separation process, formation regions where a plurality of surface emitting devices 1 is formed at one substrate 20 are separated from each other. Dicing, laser dicing, RIE, or the like is used to perform separating.

With these processes, a plurality of surface emitting devices 1 is formed, and the method of manufacturing the surface emitting device 1 according to the first embodiment ends.

### [Workings and Effects]

As illustrated in FIG. 1, the surface emitting device 1 according to the first embodiment includes the first reflective layer 2, the first semiconductor layer 3, the active layer 4, the second semiconductor layer 5, the tunnel junction layer 6, the third semiconductor layer 7, and the second reflective layer 10.

The first semiconductor layer 3 is stacked on the first reflective layer 2, and has a first conductive type. The active layer 4 is stacked on the first semiconductor layer 3. The second semiconductor layer 5 is stacked on the active layer 4, and has a second conductive type. The tunnel junction layer 6 is stacked on the second semiconductor layer 5. The third semiconductor layer 7 is stacked on the tunnel junction layer 6, and has the first conductive type. The second reflective layer 10 is stacked on the third semiconductor layer 7 at the opposite side to the first reflective layer 2 side. In addition, the surface emitting device 1 further includes the dielectric layer 8 and the fourth semiconductor layer 9. Between the third semiconductor layer 7 and the fourth semiconductor layer 9, the dielectric layer 8 is stacked on the third semiconductor layer 7. The dielectric layer 8 has the aperture 81. The dielectric layer 8 is formed through non-selective oxidation. Within the aperture 81, the fourth semiconductor layer 9 is stacked on the third semiconductor layer 7, and is formed through selective growth of the third semiconductor layer 7. Here, the second reflective layer 10 is stacked on the fourth semiconductor layer 9.

Here, the dielectric layer 8 has the aperture 81, and the aperture 81 is used as a current path. The dielectric layer 8 blocks a flow of a current at a region other than the aperture 81, and functions as a current confining layer. In addition, the dielectric layer 8 suppresses spreading of light into a region other than the aperture 81, and function as a light confining layer.

Furthermore, the dielectric layer 8 is formed through non-selective oxidation. Specifically, the dielectric layer 8 is a deposited film, rather than an oxidized layer formed through selective oxidation of a compound semiconductor such as AlInAs. Thus, the dielectric layer 8 is manufactured through a manufacturing method widely used in a semiconductor manufacturing technique. This makes it possible to form the dielectric layer 8 in a simplified manner and within a reduced period of time.

Thus, it is possible to provide the surface emitting device 1 that makes it possible to achieve current confining and light confining with a simplified structure.

In addition, in the surface emitting device 1, the first semiconductor layer 3 and the third semiconductor layer 7 are of an n-type, or are at least partially non-doped, as illustrated in FIG. 1. Furthermore, the second semiconductor layer 5 is of a p-type, or is at least partially non-doped. Specifically, the third semiconductor layer 7 directly above the tunnel junction layer 6 is set to be of an n-type. The n-type third semiconductor layer 7 has a lower resistance and absorbs less light than a p-type semiconductor layer.

Thus, as compared with a p-type semiconductor layer, it is possible to improve an electrical property and an optical property, even if the aperture diameter of the aperture 81 of the dielectric layer 8 is increased, or even if the n-type fourth semiconductor layer 9 is formed so as to be thick.

In addition, in the surface emitting device 1, the active layer 4 includes at least one element selected from Al, Ga, and In of group III elements, and at least one element selected from As, P, and N of group V elements, as illustrated in FIG. 1. Here, the active layer 4 includes AlGaInAs. Thus, it is possible to achieve the surface emitting device 1 using a group III-group V compound semiconductor.

In addition, in the surface emitting device 1, the active layer 4 includes a quantum well, a quantum wire, or a quantum dot, as illustrated in FIG. 1. In particular, in the surface emitting device 1 according to the first embodiment, the active layer 4 is configured as a strain-compensated quantum well including non-doped AlGaInAs. The active layer 4 configured as the strain-compensated quantum well makes it possible to improve a gain.

Furthermore, in the surface emitting device 1, the dielectric layer 8 illustrated in FIG. 1 includes a material containing, as a component, at least one selected from SiOx, SiNx, and the like, or at least one selected from LiF, KF, and the like, where x is greater than 0, as described above. That is, the material of the dielectric layer 8 is selectable from a number of materials. This makes it possible to select a material for the dielectric body of the dielectric layer 8 so as to correspond to a desired optical property on an as-necessary basis to manufacture the surface emitting device 1.

In addition, in the surface emitting device 1, the aperture 81 of the dielectric layer 8 has a circular shape in plan view, as illustrated in FIGS. 1 and 2. Thus, with the surface emitting device 1, it is possible to reduce a threshold current of laser oscillation, and it is possible to improve slope efficiency.

Furthermore, in the surface emitting device 1, the first reflective layer 2 illustrated in FIG. 1 is configured by stacking at least two or more types of layers selected from InP, AlxGayIn1−x−yAs (0≤x, y≤1), and InxGa1−xAs1−yPy (0≤x, y≤1). Thus, it is possible to configure the first reflective layer 2 as a DBR having an optimum reflectivity.

In addition, in the surface emitting device 1, the second reflective layer 10 illustrated in FIG. 1 is formed by stacking at least two or more types of dielectric materials. For example, by alternately stacking SiO2 and Ta2O5 a plurality of times, it is possible to configure the second reflective layer 10 as a DBR having an optimum reflectivity.

Furthermore, the surface emitting device 1 includes the first electrode 11 and the second electrode 12, as illustrated in FIG. 1. The first electrode 11 is electrically coupled to the first semiconductor layer 3 through the first reflective layer 2 or a clad layer. The second electrode is electrically coupled to the third semiconductor layer 7 with the fourth semiconductor layer 9 being interposed therebetween. Thus, it is possible to reliably cause a current to flow through the surface emitting device 1 in a simplified manner.

### First Modification Example

The first modification example to the third modification example each describe an example in which the shape of the aperture 81 of the dielectric layer 8 is modified in the surface emitting device 1.

Note that, in the first modification example, modification examples subsequent thereto, a second embodiment that will be described later, and embodiments subsequent thereto, the same reference characters are attached to the same constituent elements or substantially the same constituent elements as the constituent elements of the surface emitting device 1 according to the first embodiment, and explanation thereof will not be repeated.

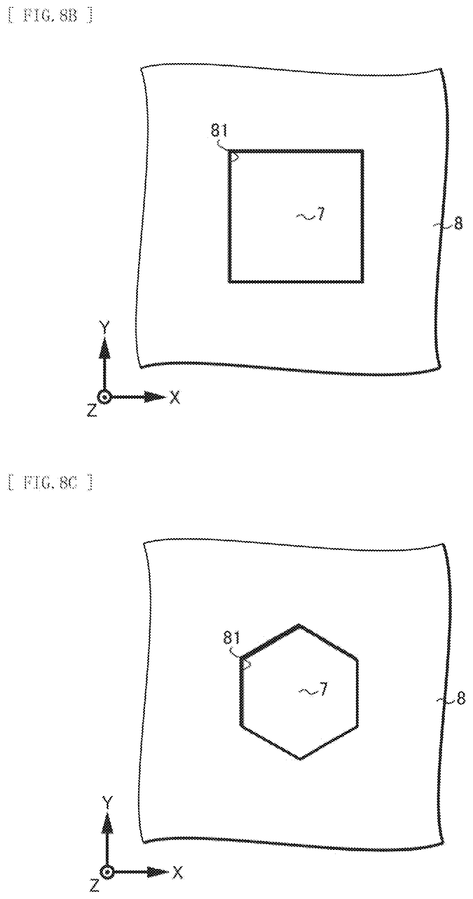

FIG. 8A illustrates the shape of the aperture 81 of the dielectric layer 8 of a surface emitting device 1 according to the first modification example of the first embodiment. In the surface emitting device 1 according to the first modification example, the aperture 81 of the dielectric layer 8 is formed into an oval shape in plan view.

With the surface emitting device 1 according to the first modification example having such a configuration, it is possible to obtain workings and effects similar to those obtained from the surface emitting device 1 according to the first embodiment.

In addition, with the surface emitting device 1, since the aperture 81 of the dielectric layer 8 is formed into an oval shape, it is possible to adjust the transverse mode or polarization of optical output.

### Second Modification Example

FIG. 8B illustrates the shape of the aperture 81 of the dielectric layer 8 of a surface emitting device 1 according to the second modification example of the first embodiment. In the surface emitting device 1 according to the second modification example, the aperture 81 of the dielectric layer 8 is formed into a rectangular shape in plan view. Here, the aperture 81 is formed into a square shape. In addition, the aperture 81 may be formed into a rectangular shape.

With the surface emitting device 1 according to the second modification example having such a configuration, it is possible to obtain workings and effects similar to those obtained from the surface emitting device 1 according to the first modification example.

### Third Modification Example

FIG. 8C illustrates the shape of the aperture 81 of the dielectric layer 8 of a surface emitting device 1 according to the third modification example of the first embodiment. In the surface emitting device 1 according to the third modification example, the aperture 81 of the dielectric layer 8 is formed into a polygonal shape in plan view. Here, the aperture 81 is formed into a regular hexagonal shape. In addition, the aperture 81 may be formed into a triangle shape, a pentagon shape, a heptagonal shape, or a polygonal shape having more sides.

With the surface emitting device 1 according to the third modification example having such a configuration, it is possible to obtain workings and effects similar to those obtained from the surface emitting device 1 according to the first modification example.

Note that at least a portion of the aperture 81 may be formed into an asymmetrical shape in plan view.

### 2. Second Embodiment

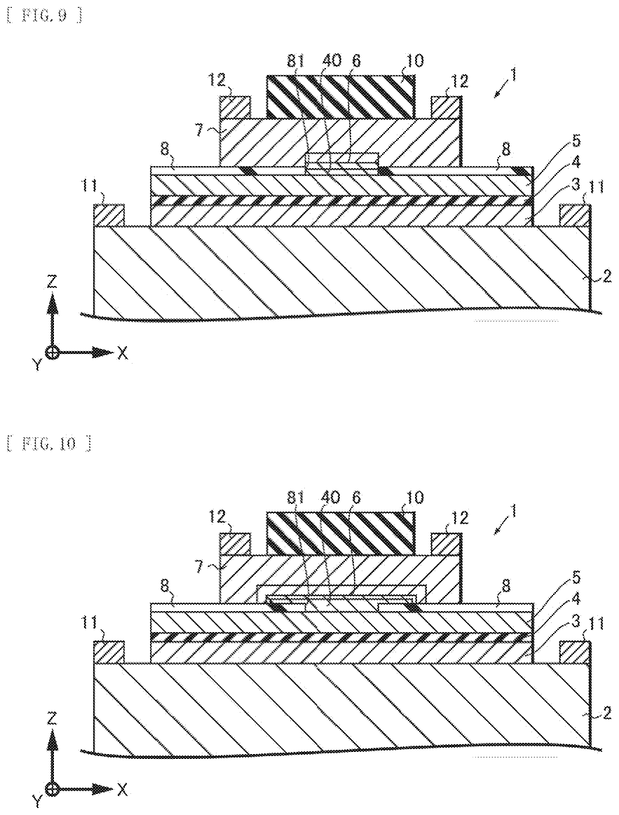

FIG. 9 illustrates one example of the configuration, in longitudinal cross section, of a surface emitting device 1 according to the second embodiment of the present disclosure.

In the surface emitting device 1 according to the second embodiment, the dielectric layer 8 is stacked on the second semiconductor layer 5 and is disposed between the second semiconductor layer 5 and the third semiconductor layer 7. In addition, within the aperture 81 of the dielectric layer 8, a fourth semiconductor layer 40 formed through selective growth of the second semiconductor layer 5 is stacked on the second semiconductor layer 5. The tunnel junction layer 6 is stacked on this fourth semiconductor layer 40. In addition, within the aperture 81, the third semiconductor layer 7 is stacked on the tunnel junction layer 6, and outside of the aperture 81, the third semiconductor layer 7 is also stacked, through ELO, on the dielectric layer 8.

Note that, in the second embodiment, the dielectric layer 8 is stacked on the second semiconductor layer 5. In addition, within the aperture 81 of the dielectric layer 8, the fourth semiconductor layer 40 is stacked on the second semiconductor layer 5. The fourth semiconductor layer 40 is formed through re-crystal growth of the second semiconductor layer 5, and hence, corresponds to a “fourth semiconductor layer” according to the present technology.

Configurations of the surface emitting device 1 other than those described above are the same as the configurations of the surface emitting device 1 according to the first embodiment.

With the surface emitting device 1 according to the second embodiment, it is possible to obtain workings and effects similar to those obtained from the surface emitting device 1 according to the first embodiment.

### 3. Third Embodiment

FIG. 10 illustrates one example of the configuration, in longitudinal cross section, of a surface emitting device 1 according to the third embodiment of the present disclosure.

In the surface emitting device 1 according to the third embodiment, the dielectric layer 8 is stacked on the second semiconductor layer 5, as in the surface emitting device 1 according to the second embodiment. The fourth semiconductor layer 40 is stacked on the second semiconductor layer 5 within the aperture 81 of the dielectric layer 8. The tunnel junction layer 6 and the third semiconductor layer 7 are sequentially stacked on the fourth semiconductor layer 40. Outside of the aperture 81, the tunnel junction layer 6 and the third semiconductor layer 7 are stacked, through ELO, on the dielectric layer 8.

Configurations of the surface emitting device 1 other than those described above are the same as the configurations of the surface emitting device 1 according to the second embodiment.

With the surface emitting device 1 according to the third embodiment, it is possible to obtain workings and effects similar to those obtained from the surface emitting device 1 according to the second embodiment.

### 4. Fourth Embodiment

FIG. 11 illustrates one example of the configuration, in longitudinal cross section, of a surface emitting device 1 according to the fourth embodiment of the present disclosure.

In the surface emitting device 1 according to the fourth embodiment, a second reflective layer 10A is stacked in place of the second reflective layer 10 of the surface emitting device 1 according to the first embodiment. While the second reflective layer 10 includes the dielectric body DBR, the second reflective layer 10A includes a semiconductor DBR in which semiconductor layers having two or more types of different indices of refraction are alternately stacked a plurality of times, as with the first reflective layer 2.

Specifically, the second reflective layer 10A is configured by stacking semiconductor layers having at least two or more types of indices of refraction and selected from InP, AlxGayIn1−x−yAs (0≤ x, y≤1), and InxGa1−xAs1−yPy (0≤x, y≤1). Here, the second reflective layer 10A is formed, for example, by alternately stacking a semiconductor of n-type AlGaInAs and a semiconductor layer of n-type InP.

The second reflective layer 10A is formed on the fourth semiconductor layer 9 through continuous crystal growth.

Note that the second electrode 12 is stacked on a peripheral edge portion of the second reflective layer 10A.

Configurations of the surface emitting device 1 other than those described above are the same as the configurations of the surface emitting device 1 according to the first embodiment.

With the surface emitting device 1 according to the fourth embodiment, it is possible to obtain workings and effects similar to those obtained from the surface emitting device 1 according to the first embodiment.

### 5. Fifth Embodiment

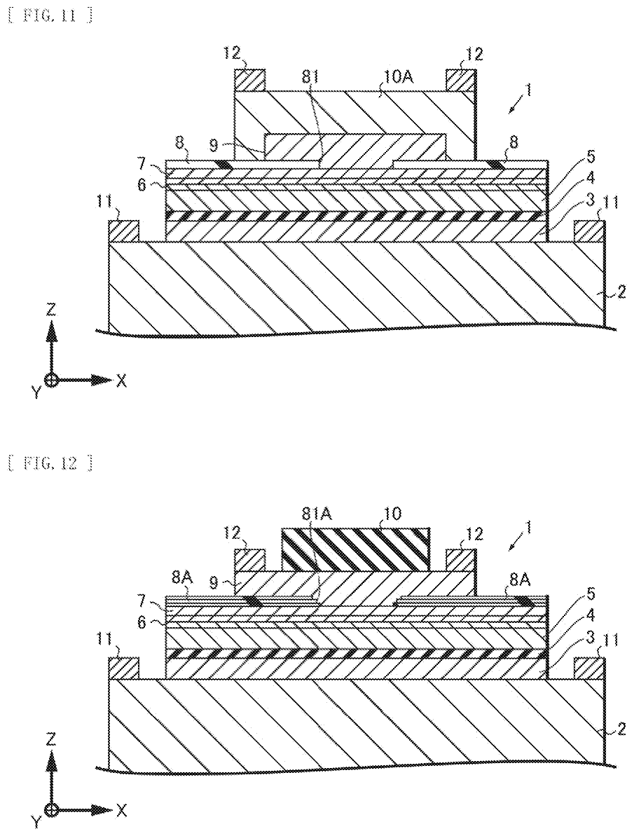

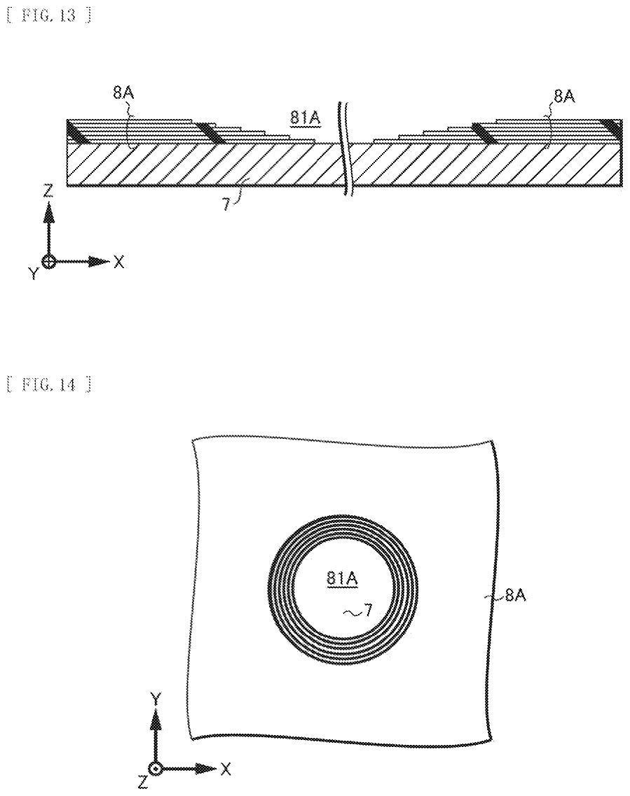

FIG. 12 illustrates one example of the configuration, in longitudinal cross section, of a surface emitting device 1 according to the fifth embodiment of the present disclosure. In addition, FIG. 13 illustrates one example of the cross-sectional configuration, in which a dielectric layer 8A and an aperture 81A of the surface emitting device 1 are enlarged. FIG. 14 illustrates a planar shape of the dielectric layer 8A and the aperture 81A.

In the surface emitting device 1 according to the fifth embodiment, the dielectric layer 8A is stacked in place of the dielectric layer 8 of the surface emitting device 1 according to the first embodiment. The dielectric layer 8A is configured by stacking two or more layers of dielectric bodies having the same index of refraction or different indices of refraction in a thickness direction or a planar direction. The dielectric bodies may include the same dielectric material or may include different dielectric materials.

Here, for example, the same SiO2 is used for the dielectric materials. The thickness of SiO2 of each of the layers is set to 5 nm, and the dielectric layer 8A is configured by stacking six layers of this SiO2. The aperture 81A is formed, for example, into a circular shape. The aperture 81A is configured such that the diameter of the aperture of SiO2 at an upper layer is larger, for example, by approximately 0.5 μm, than the diameter of the aperture of SiO2 at a lower layer immediately below this upper layer. That is, the diameter of the aperture of SiO2 at each of the layers gradually increases toward upper layers. In other words, the aperture 81A is formed into a pseudo tapered shape in cross section such that the diameter of the aperture at the fourth semiconductor layer 9 side is wider than the diameter of the aperture at the third semiconductor layer 7 side

Configurations of the surface emitting device 1 other than those described above are the same as the configurations of the surface emitting device 1 according to the first embodiment.

With the surface emitting device 1 according to the fifth embodiment, it is possible to obtain workings and effects similar to those obtained from the surface emitting device 1 according to the first embodiment. In addition, in the surface emitting device 1, the dielectric layer 8A is configured by stacking two or more layers of dielectric bodies having the same index of refraction or different indices of refraction in a thickness direction or a planar direction, as illustrated in FIGS. 12 to 14. This makes it possible to adjust the index of refraction in a three-dimensional manner, as compared with the dielectric layer 8 and the aperture 81 having a single layer structure. Thus, with the dielectric layer 8A and the aperture 81A, it is possible to make adjustment to a single transverse mode while reducing a dispersion loss of laser light.

### First Modification Example

The first modification example to the third modification example each describe an example in which the shape of the aperture 81A of the dielectric layer 8A is modified in the surface emitting device 1.

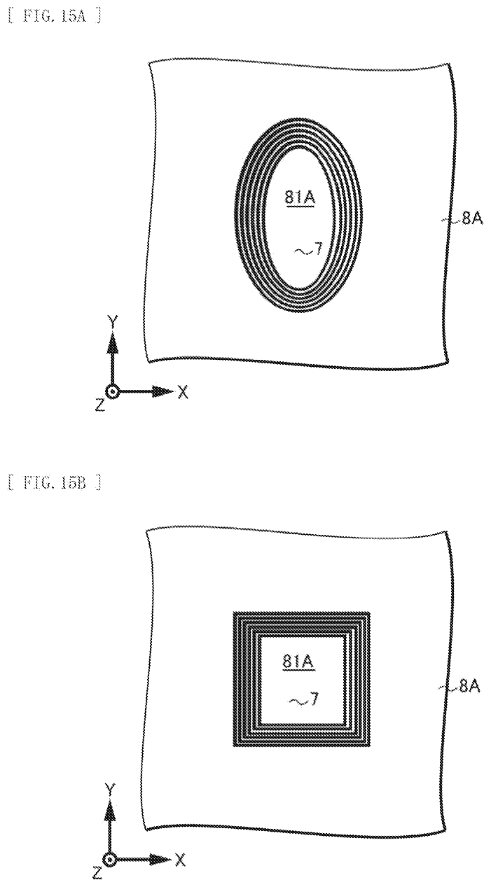

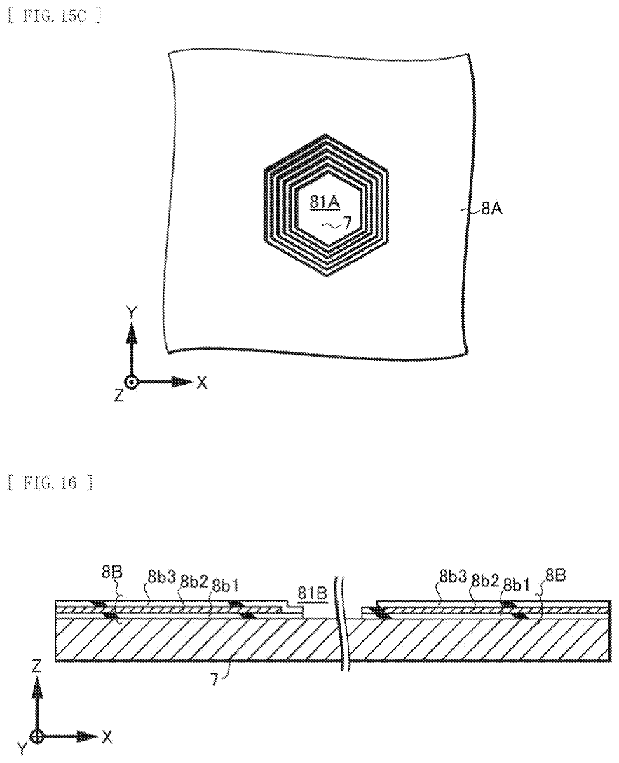

FIG. 15A illustrates the shape of the aperture 81A of the dielectric layer 8A of a surface emitting device 1 according to the first modification example of the fifth embodiment. In the surface emitting device 1 according to the first modification example, the aperture 81A of the dielectric layer 8A is formed into an oval shape in plan view, as with the aperture 81 of the dielectric layer 8 of the surface emitting device 1 according to the first modification example of the first embodiment.

With the surface emitting device 1 according to the first modification example having such a configuration, it is possible to obtain workings and effects similar to those obtained from the surface emitting device 1 according to the fifth embodiment.

### Second Modification Example

FIG. 15B illustrates the shape of the aperture 81A of the dielectric layer 8A of a surface emitting device 1 according to the second modification example of the fifth embodiment. In the surface emitting device 1 according to the second modification example, the aperture 81A of the dielectric layer 8A is formed into a rectangular shape in plan view, as with the aperture 81 of the dielectric layer 8 of the surface emitting device 1 according to the second modification example of the first embodiment.

With the surface emitting device 1 according to the second modification example having such a configuration, it is possible to obtain workings and effects similar to those obtained from the surface emitting device 1 according to the first modification example.

### Third Modification Example

FIG. 15C illustrates the shape of the aperture 81A of the dielectric layer 8A of a surface emitting device 1 according to the third modification example of the fifth embodiment. In the surface emitting device 1 according to the third modification example, the aperture 81A of the dielectric layer 8A is formed into a polygonal shape in plan view, as with the aperture 81 of the dielectric layer 8 of the surface emitting device 1 according to the third modification example of the first embodiment.

With the surface emitting device 1 according to the third modification example having such a configuration, it is possible to obtain workings and effects similar to those obtained from the surface emitting device 1 according to the first modification example.

Note that at least a portion of the aperture 81A may be formed into an asymmetrical shape in plan view.

### 6. Sixth Embodiment

FIG. 16 illustrates one example of the cross-sectional configuration of a dielectric layer 8B and an aperture 81B of a surface emitting device 1 according to a sixth embodiment of the present disclosure.

In the surface emitting device 1 according to the sixth embodiment, the dielectric layer 8B is stacked, in place of the dielectric layer 8 of the surface emitting device 1 according to the first embodiment. A material that absorbs light is used for all of or a portion of the dielectric layer 8B. Here, a metal layer 8b2 that absorbs light is stacked to form the dielectric layer 8B.

Specifically, the dielectric layer 8B is formed, for example, by sequentially stacking a dielectric body 8b1, the metal layer 8b2 on the dielectric body 8b1, and a dielectric body 8b3 on the metal layer 8b2. For example, SiO2 is used for the dielectric body 8b1, and SiO2 is formed so as to have a thickness of 10 nm. For example, Ti is used for the metal layer 8b2, and Ti is formed so as to have a thickness of 10 nm. For example, SiO2 is used for the dielectric body 8b3, and SiO2 is formed so as to have a thickness of 10 nm.

At the inner side of the aperture 81B, the diameter of an end portion of the metal layer 8b2 is larger than the diameter of an end portion of the dielectric body 8b1 and the diameter of an end portion of the dielectric body 8b3. In addition, the end portion of the dielectric body 8b1 and the end portion of the dielectric body 8b3 are coupled to each other. That is, the end portion of the metal layer 8b2 is structured so as not to be exposed from a coupling portion between the end portion of the dielectric body 8b1 and the end portion of the dielectric body 8b3. With this configuration, for example, when Ti is used for the metal layer 8b2, it is possible to prevent Ti from spreading.

Configurations of the surface emitting device 1 other than those described above are the same as the configurations of the surface emitting device 1 according to the first embodiment.

With the surface emitting device 1 according to the sixth embodiment, it is possible to obtain workings and effects similar to those obtained from the surface emitting device 1 according to the first embodiment.

In addition, in the surface emitting device 1, a material that absorbs light is used for all of or a portion of the dielectric layer 8B, as illustrated in FIG. 16. Alternatively, the dielectric layer 8B is configured such that the metal layer 8b2 that absorbs light is stacked. Thus, it is possible to provide an absorption loss at a high-dimensional mode, and make adjustment to a single transverse mode.

### 7. Seventh Embodiment

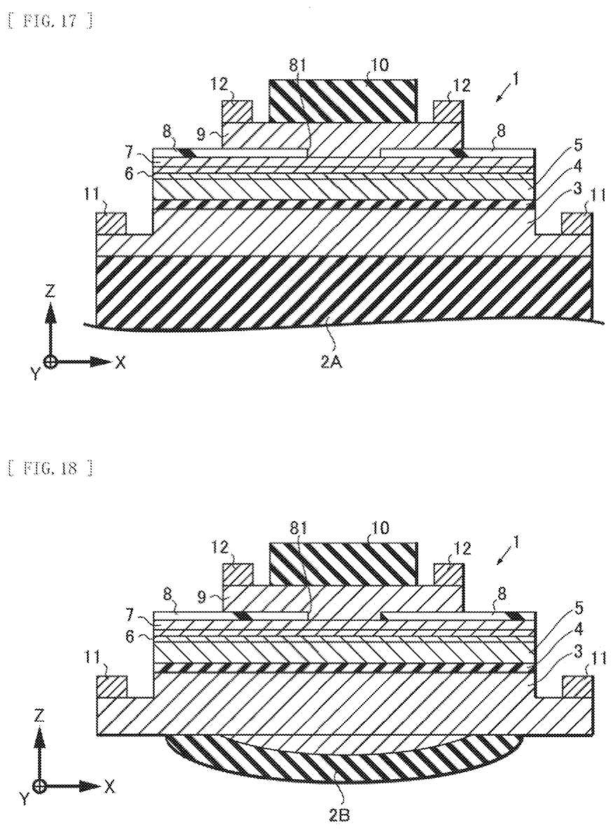

FIG. 17 illustrates one example of the configuration, in longitudinal cross section, of a surface emitting device 1 according to the seventh embodiment of the present disclosure.

In the surface emitting device 1 according to the seventh embodiment, a first reflective layer 2A is formed, in place of the first reflective layer 2 of the surface emitting device 1 according to the first embodiment. The first reflective layer 2A is bonded to the first semiconductor layer 3.

The first reflective layer 2A includes AlxGa1−xAs (0≤x≤1) having at least two or more types of different compositions. Specifically, the first reflective layer 2A is formed, for example, by alternately stacking GaAs and AlGaAs a plurality of times.

Here, the first reflective layer 2A is configured as a semiconductor DBR including a semiconductor material differing from that of the first reflective layer 2. The first reflective layer 2A has a less thermal resistance and a wider stopband width than those of the first reflective layer 2 of the surface emitting device 1 according to the first embodiment.

Configurations of the surface emitting device 1 other than those described above are the same as the configurations of the surface emitting device 1 according to the first embodiment.

With the surface emitting device 1 according to the seventh embodiment, it is possible to obtain workings and effects similar to those obtained from the surface emitting device 1 according to the first embodiment.

In addition, the surface emitting device 1 includes the first reflective layer 2A as illustrated in FIG. 17. Thus, it is possible to achieve the surface emitting device 1 having a less thermal resistance and a wider stopband width than those of the first reflective layer 2 of the surface emitting device 1 according to the first embodiment.

### 8. Eighth Embodiment

FIG. 18 illustrates one example of the configuration, in longitudinal cross section, of a surface emitting device 1 according to the eighth embodiment of the present disclosure.

In the surface emitting device 1 according to the eighth embodiment, a first reflective layer 2B is stacked, in place of the first reflective layer 2 of the surface emitting device 1 according to the first embodiment. The first reflective layer 2B is configured as a lens-type reflective layer in which the middle portion thereof protrudes toward a side opposite to the second reflective layer 10 side. The first reflective layer 2B is configured as a dielectric body DBR in which dielectric bodies having two or more types of different indices of refraction are alternately stacked a plurality of times, as with the second reflective layer 10.

In addition, by using a mask formed using a photolithography technique and also using a dry etching technique such as RIE, it is possible to form a protruding portion at the back surface of a substrate that is a side at which the first reflective layer 2B is stacked.

Configurations of the surface emitting device 1 other than those described above are the same as the configurations of the surface emitting device 1 according to the first embodiment.

With the surface emitting device 1 according to the eighth embodiment, it is possible to obtain workings and effects similar to those obtained from the surface emitting device 1 according to the first embodiment.

In addition, the surface emitting device 1 includes the first reflective layer 2B as a lens-type reflective layer, as illustrated in FIG. 18. In the surface emitting device 1, this makes it possible to reduce a diffraction loss of light, which makes it possible to achieve a reduction in threshold current density of laser oscillation and also achieve increased slope.

### 9. Ninth Embodiment

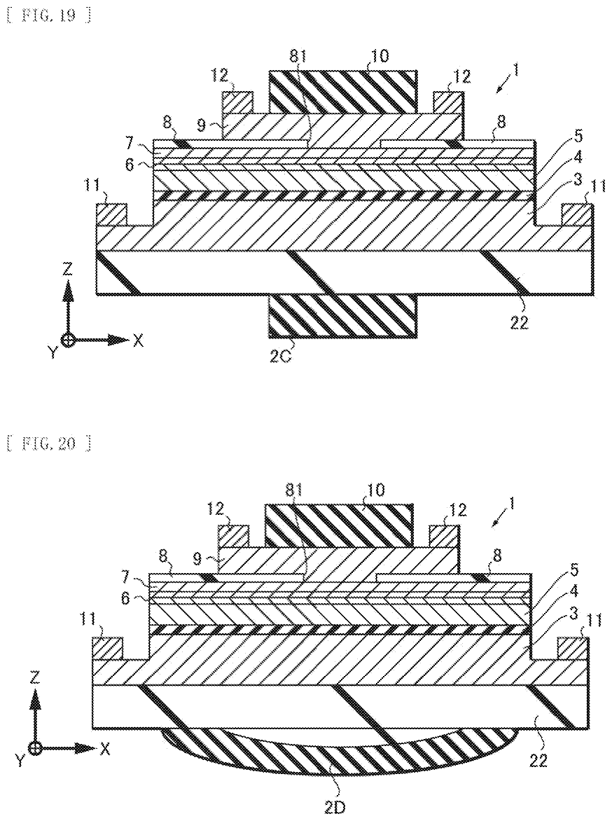

FIG. 19 illustrates one example of the configuration, in longitudinal cross section, of a surface emitting device 1 according to the ninth embodiment of the present disclosure.

In the surface emitting device 1 according to the ninth embodiment, a first reflective layer 2C is stacked, in place of the first reflective layer 2 of the surface emitting device 1 according to the first embodiment. The first reflective layer 2C is stacked at the first semiconductor layer 3 with the foreign substrate 22 being interposed therebetween.

The first reflective layer 2C is configured, for example, with a dielectric body DBR in which SiO2 and Ta2O5 are alternately stacked a plurality of times, as with the second reflective layer 10 of the surface emitting device 1 according to the first embodiment. The foreign substrate 22 includes, as a main component, at least one selected from GaAs, Si, GaN, AlN, BN, and SiC, for example. These materials exhibit an excellent heat dissipating property, and show significantly low absorption for a wavelength of light emitted by the surface emitting device 1. The foreign substrate 22 is configured as a portion of a cavity.

Configurations of the surface emitting device 1 other than those described above are the same as the configurations of the surface emitting device 1 according to the first embodiment.

With the surface emitting device 1 according to the ninth embodiment, it is possible to obtain workings and effects similar to those obtained from the surface emitting device 1 according to the first embodiment.

In addition, the surface emitting device 1 includes a first reflective layer 2C with the foreign substrate 22 being interposed therebetween below the first semiconductor layer 3, as illustrated in FIG. 19. Thus, it is possible to achieve the surface emitting device 1 having a low thermal resistance.

### 10. Tenth Embodiment

FIG. 20 illustrates one example of the configuration, in longitudinal cross section, of a surface emitting device 1 according to the tenth embodiment of the present disclosure. The surface emitting device 1 according to the tenth embodiment is configured by combining the surface emitting device 1 according to the eighth embodiment and the surface emitting device 1 according to the ninth embodiment together. That is, in the surface emitting device 1, a first reflective layer 2D serving as a lens-type reflective layer is stacked below the first semiconductor layer 3 with the foreign substrate 22 being interposed therebetween. The first reflective layer 2D is configured with a dielectric body DBR, as with the first reflective layer 2C.

With the surface emitting device 1 according to the tenth embodiment, it is possible to obtain workings and effects obtained by combining the workings and effects obtained from the surface emitting device 1 according to the eighth embodiment and the workings and effects obtained from the surface emitting device 1 according to the ninth embodiment.

### 11. Eleventh Embodiment

FIG. 21 illustrates one example of the configuration, in longitudinal cross section, of a surface emitting device 1 according to the eleventh embodiment of the present disclosure. The surface emitting device 1 according to the eleventh embodiment includes a second reflective layer 10B, in place of the second reflective layer 10 of the surface emitting device 1 according to the first embodiment. The second reflective layer 10B is configured as a lens-type reflective layer in which the middle portion thereof protrudes toward a side opposite to the first reflective layer 2 side. The second reflective layer 10B is stacked on the fourth semiconductor layer 9. The second reflective layer 10B is configured as a dielectric body DBR in which dielectric bodies having two or more types of different indices of refraction are alternately stacked a plurality of times, as with the first reflective layer 2B of the surface emitting device 1 according to the eighth embodiment.

Configurations of the surface emitting device 1 other than those described above are the same as the configurations of the surface emitting device 1 according to the first embodiment.

With the surface emitting device 1 according to the eleventh embodiment, it is possible to obtain workings and effects obtained by combining the workings and effects obtained from the surface emitting device 1 according to the first embodiment and the workings and effects obtained from the surface emitting device 1 according to the eighth embodiment.

### 12. Twelfth Embodiment

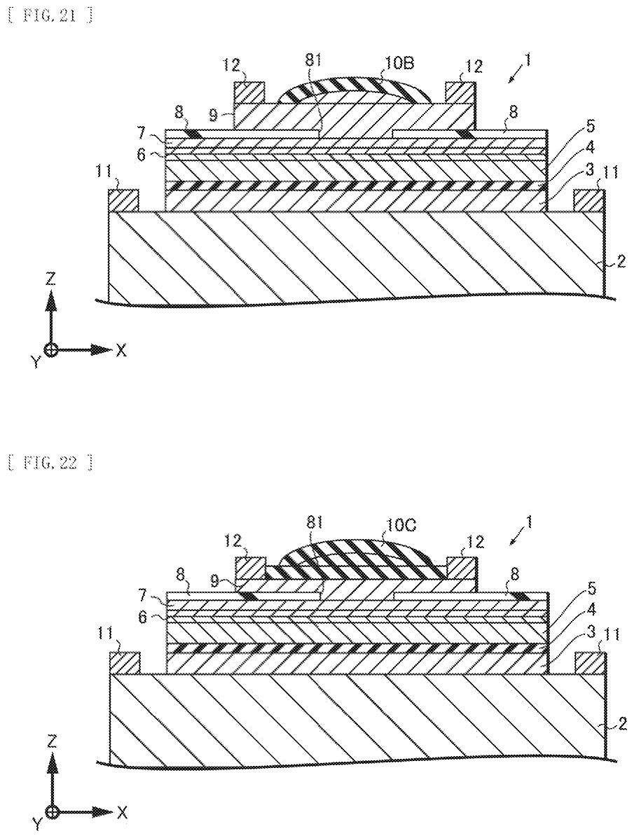

FIG. 22 illustrates one example of the configuration, in longitudinal cross section, of a surface emitting device 1 according to the twelfth embodiment of the present disclosure.

The surface emitting device 1 according to the twelfth embodiment includes a second reflective layer 10C, in place of the second reflective layer 10B of the surface emitting device 1 according to the eleventh embodiment. The second reflective layer 10C is configured as a lens-type reflective layer in which the middle portion thereof protrudes toward a side opposite to the first reflective layer 2 side. The second reflective layer 10C is stacked on the fourth semiconductor layer 9. The second reflective layer 10C is configured with a dielectric body DBR.

Configurations of the surface emitting device 1 other than those described above are the same as the configurations of the surface emitting device 1 according to the first embodiment.

With the surface emitting device 1 according to the twelfth embodiment, it is possible to obtain workings and effects similar to those obtained from the surface emitting device 1 according to the eleventh embodiment.

### 13. Thirteenth Embodiment

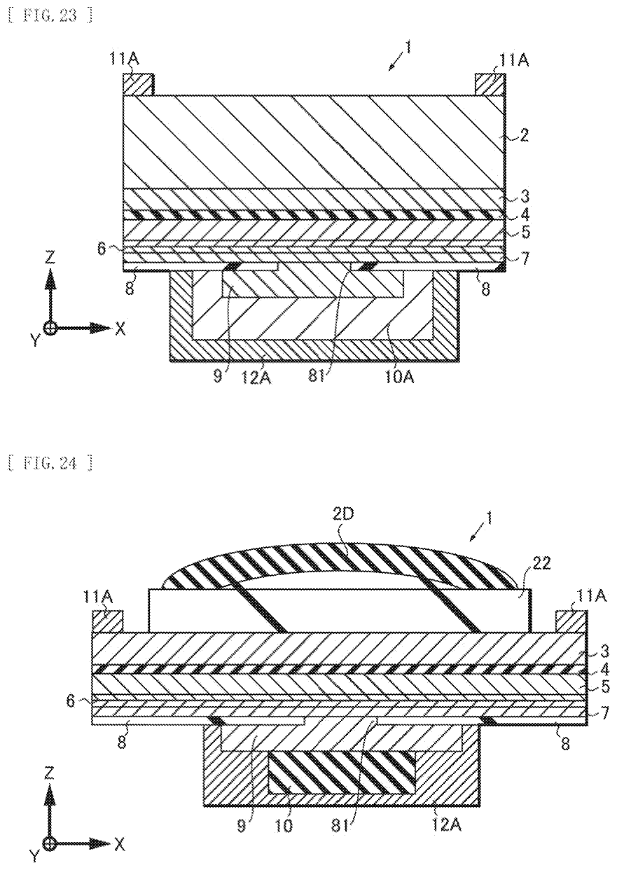

FIG. 23 illustrates one example of the configuration, in longitudinal cross section, of a surface emitting device 1 according to the thirteenth embodiment of the present disclosure.

The surface emitting device 1 according to the thirteenth embodiment provides an application example of the surface emitting device 1 according to the fourth embodiment, and is configured to have a back-side emitting structure. That is, in the surface emitting device 1, the stacking structure is configured upside down by sequentially stacking the first reflective layer 2, the first semiconductor layer 3, the active layer 4, the second semiconductor layer 5, the tunnel junction layer 6, the third semiconductor layer 7, the dielectric layer 8, the fourth semiconductor layer 9, and the second reflective layer 10 from the upper side toward the lower side.

A first electrode 11A is stacked on a peripheral edge portion of the first reflective layer 2. A second electrode 12A is formed below the second reflective layer 10 so as to cover substantially the entire area of the second reflective layer 10. In addition, laser light is outputted upward.

Configurations of the surface emitting device 1 other than those described above are the same as the configurations of the surface emitting device 1 according to the fourth embodiment.

With the surface emitting device 1 according to the thirteenth embodiment, it is possible to obtain workings and effects similar to those obtained from the surface emitting device 1 according to the fourth embodiment.

### 14. Fourteenth Embodiment

FIG. 24 illustrates one example of the configuration, in longitudinal cross section, of a surface emitting device 1 according to the fourteenth embodiment of the present disclosure. The surface emitting device 1 according to the fourteenth embodiment is configured to have a back-side emitting structure, as with the surface emitting device 1 according to the thirteenth embodiment. In addition, in the surface emitting device 1, the first reflective layer 2D is stacked at the first semiconductor layer 3 with the foreign substrate 22 being interposed therebetween, as with the surface emitting device 1 according to the tenth embodiment. The first reflective layer 2D is configured as a lens-type reflective layer, and is also configured with a dielectric body DBR.

Configurations of the surface emitting device 1 other than those described above are the same as the configurations of the surface emitting device 1 according to the tenth embodiment and the configurations of the surface emitting device 1 according to the thirteenth embodiment.

With the surface emitting device 1 according to the fourteenth embodiment, it is possible to obtain workings and effects obtained by combining the workings and effects obtained from the surface emitting device 1 according to the tenth embodiment and the workings and effects obtained from the surface emitting device 1 according to the thirteenth embodiment.

### 15. Other Embodiments

The present technology should not be limited to the embodiments described above, and it is possible to make various modifications within the scope of the main points of the present technology.

For example, in the present technology, it is possible to combine together two or more of the surface emitting devices according to the plurality of embodiments described above or a plurality of modification examples described above.

In the present disclosure, the surface emitting device includes a first reflective layer, a first semiconductor layer, an active layer, a second semiconductor layer, a tunnel junction layer, a third semiconductor layer, and a second reflective layer. The first semiconductor layer is stacked on the first reflective layer and has a first conductive type. The active layer is stacked on the first semiconductor layer. The second semiconductor layer is stacked on the active layer and has a second conductive type. The tunnel junction layer is stacked on the second semiconductor layer. The third semiconductor layer is stacked on the tunnel junction layer and has the first conductive type. The second reflective layer is stacked on the third semiconductor layer, at an opposite side to the first reflective layer side. In addition, the surface emitting device further includes a dielectric layer and a fourth semiconductor layer. The dielectric layer is formed, through non-selective oxidation, between the second semiconductor layer and the third semiconductor layer or between the third semiconductor layer and the second reflective layer, and has an aperture penetrating through in a thickness direction. The fourth semiconductor layer is stacked, within the aperture, on the second semiconductor layer or the third semiconductor layer, and is formed through selective growth of the second semiconductor layer or the third semiconductor layer.

Here, the dielectric layer functions as a current confining layer and a light confining layer. In addition, since the dielectric layer is formed through non-selective oxidation, it is possible to form the dielectric layer in a simplified manner and within a reduced period of time.

Thus, it is possible to provide the surface emitting device that makes it possible to achieve current confining and light confining with a simplified structure.

### <Configuration of Present Technology>

The present technology has the following configurations. With the present technology having the following configurations, it is possible to provide the surface emitting device that makes it possible to achieve current confining and light confining with a simplified structure.

(1)

A surface emitting device including:
a first reflective layer:
a first semiconductor layer of a first conductive type, the first semiconductor layer being stacked on the first reflective layer;
an active layer stacked on the first semiconductor layer:
a second semiconductor layer of a second conductive type that is a conductive type opposite to the first conductive type, the second semiconductor layer being stacked on the active layer:
a tunnel junction layer stacked on the second semiconductor layer:
a third semiconductor layer of the first conductive type, the third semiconductor layer being stacked on the tunnel junction layer:
a second reflective layer stacked on the third semiconductor layer, at a side opposite to a side of the first reflective layer:
a dielectric layer formed, through non-selective oxidation, between the second semiconductor layer and the third semiconductor layer or between the third semiconductor layer and the second reflective layer, the dielectric layer having an aperture penetrating through in a thickness direction; and
a fourth semiconductor layer stacked, within the aperture, on the second semiconductor layer or the third semiconductor layer and formed through selective growth of the second semiconductor layer or the third semiconductor layer.
   (2)

The surface emitting device according to (1) described above, in which the dielectric layer includes a deposited film.

(3)

The surface emitting device according to (1) or (2) described above, in which
the first semiconductor layer and the third semiconductor layer are of an n-type, or the first semiconductor layer and the third semiconductor layer are at least partially non-doped, and
the second semiconductor layer is of a p-type, or the second semiconductor layer is at least partially non-doped.
   (4)

The surface emitting device according to any one of (1) to (3) described above, in which
the active layer includes:
   at least one element selected from Al, Ga, and In of group III elements; and
   at least one element selected from As, P, and N of group V elements.
      (5)

The surface emitting device according to any one of (1) to (4) described above, in which the active layer includes a quantum well, a quantum wire, or a quantum dot.

(6)

The surface emitting device according to any one of (1) to (5) described above, in which
the dielectric layer includes a material containing, as a component, at least one selected from SiOx, SiNx, AlOx, AlNx, BNx, GaOx, GaNx, HfOx, GdOx, BeOx, MgOx, CaOx, InOx, GeOx, WOx, TaOx, TiOx, NbOx, VOx, ScOx, CrOx, FeOx, CoOx, NiOx, CuOx, ZnOx, ZrOx, MoOx, TeOx, BiOx, SrOx, YOx, ScOx, MnOx, EuOx, LaOx, NdOx, DyOx, CeOx, YbOx, and ErOx, where x is greater than 0, or containing, as a component, at least one selected from LiF, KF, CaF2, GaF3, ZnF2, CoF2, AlF2, PbF2, InF3, CrF3, FeF3, NiF2, CuF2, BiF3, MnF2, SnF4, BaF2, ZrF4, AlF3, LaF, MnF2, SrF2, MgS, ZnS, ZnSe, MgTe, ZnTe, GeS2, SiS2, and SiC.
   (7)

The surface emitting device according to any one of (1) to (6) described above, in which
the dielectric layer is configured by stacking two or more layers of dielectric bodies having a same index of refraction or having different indices of refraction in the thickness direction or a planar direction.
   (8)

The surface emitting device according to any one of (1) to (7) described above, in which
as viewed from the thickness direction of the dielectric layer, the aperture has a circular shape, an oval shape, a rectangular shape, or a polygonal shape, or at least a portion of the aperture has an asymmetrical shape.
   (9)

The surface emitting device according to any one of (1) to (8) described above, in which all of or a portion of the dielectric layer includes a material that absorbs light.

(10)

The surface emitting device according to any one of (1) to (9) described above, in which a metal layer that absorbs light is stacked on a portion of the dielectric layer.

(11)

The surface emitting device according to any one of (1) to (10) described above, in which
the first reflective layer or the second reflective layer is configured by stacking at least two or more types of layers selected from InP, AlxGayIn1−x−y As (0≤x, y≤1), and InxGa1−xAs1−yPy (0≤x, y≤1).
   (12)

The surface emitting device according to any one of (1) to (11) described above, in which
the first reflective layer or the second reflective layer includes AlxGa1−xAs (0≤x≤1) having at least two or more types of different compositions.
   (13)

The surface emitting device according to any one of (1) to (12) described above, in which
the first reflective layer or the second reflective layer includes a material having a less thermal resistance and a wider stopband width than a reflective layer formed by stacking InP and AlxGayIn1−x−y As (0≤x, y≤1).
   (14)

The surface emitting device according to any one of (1) to (13) described above, in which the first reflective layer or the second reflective layer is formed by stacking at least two or more types of dielectric materials.

(15)

The surface emitting device according to any one of (1) to (14) described above, in which the first reflective layer or the second reflective layer includes a lens-type reflective layer.

(16)

The surface emitting device according to any one of (1) to (15) described above, in which
the first reflective layer or the second reflective layer is stacked on the first semiconductor layer, the third semiconductor layer, or the fourth semiconductor layer with at least one foreign substrate being interposed therebetween, the foreign substrate being selected from GaAs, Si, GaN, AlN, BN, and SiC.
   (17)

The surface emitting device according to any one of (1) to (16) described above, further including:
a first electrode electrically coupled to the first reflective layer or a clad layer; and
a second electrode electrically coupled to the third semiconductor layer.

This application claims priority based on Japanese Patent Application No. 2021-131686 filed on Aug. 12, 2021 with Japan Patent Office, the entire contents of which are incorporated in this application by reference.

It should be understood by those skilled in the art that various modifications, combinations, sub-combinations and alterations may occur depending on design requirements and other factor, and they are within the scope of the appended claims or the equivalents thereof.

1. A surface emitting device comprising:
a first reflective layer;
a first semiconductor layer of a first conductive type, the first semiconductor layer being stacked on the first reflective layer;
an active layer stacked on the first semiconductor layer;
a second semiconductor layer of a second conductive type that is a conductive type opposite to the first conductive type, the second semiconductor layer being stacked on the active layer;
a tunnel junction layer stacked on the second semiconductor layer;
a third semiconductor layer of the first conductive type, the third semiconductor layer being stacked on the tunnel junction layer;
a second reflective layer stacked on the third semiconductor layer, at a side opposite to a side of the first reflective layer;
a dielectric layer formed, through non-selective oxidation, between the second semiconductor layer and the third semiconductor layer or between the third semiconductor layer and the second reflective layer, the dielectric layer having an aperture penetrating through in a thickness direction; and
a fourth semiconductor layer stacked, within the aperture, on the second semiconductor layer or the third semiconductor layer and formed through selective growth of the second semiconductor layer or the third semiconductor layer.

2. The surface emitting device according to claim 1, wherein the dielectric layer comprises a deposited film.

3. The surface emitting device according to claim 1, wherein
the first semiconductor layer and the third semiconductor layer are of an n-type, or the first semiconductor layer and the third semiconductor layer are at least partially non-doped, and
the second semiconductor layer is of a p-type, or the second semiconductor layer is at least partially non-doped.

4. The surface emitting device according to claim 1, wherein
the active layer includes:
at least one element selected from Al, Ga, and In of group III elements; and
at least one element selected from As, P, and N of group V elements.

5. The surface emitting device according to claim 1, wherein the active layer includes a quantum well, a quantum wire, or a quantum dot.

6. The surface emitting device according to claim 1, wherein
the dielectric layer includes a material containing, as a component, at least one selected from SiOx, SiNx, AlOx, AlNx, BNx, GaOx, GaNx, HfOx, GdOx, BeOx, MgOx, CaOx, InOx, GeOx, WOx, TaOx, TiOx, NbOx, VOX, ScOx, CrOx, FeOx, CoOx, NiOx, CuOx, ZnOx, ZrOx, MoOx, TeOx, BiOx, SrOx, YOx, ScOx, MnOx, EuOx, LaOx, NdOx, DyOx, CeOx, YbOx, and ErOx, where x is greater than 0, or containing, as a component, at least one selected from LiF, KF, CaF2, GaF3, ZnF2, CoF2, AlF2, PbF2, InF3, CrF3, FeF3, NiF2, CuF2, BiF3, MnF2, SnF4, BaF2, ZrF4, AlF3, LaF, MnF2, SrF2, MgS, ZnS, ZnSe, MgTe, ZnTe, GeS2, SiS2, and SiC.

7. The surface emitting device according to claim 1, wherein
the dielectric layer is configured by stacking two or more layers of dielectric bodies having a same index of refraction or having different indices of refraction in the thickness direction or a planar direction.

8. The surface emitting device according to claim 1, wherein
as viewed from the thickness direction of the dielectric layer, the aperture has a circular shape, an oval shape, a rectangular shape, or a polygonal shape, or at least a portion of the aperture has an asymmetrical shape.

9. The surface emitting device according to claim 1, wherein all of or a portion of the dielectric layer includes a material that absorbs light.

10. The surface emitting device according to claim 1, wherein a metal layer that absorbs light is stacked on a portion of the dielectric layer.

11. The surface emitting device according to claim 1, wherein
the first reflective layer or the second reflective layer is configured by stacking at least two or more types of layers selected from InP, AlxGayIn1−x−y As (0≤x, y≤1), and InxGa1−xAs1−yPy (0≤x, y≤1).

12. The surface emitting device according to claim 1, wherein
the first reflective layer or the second reflective layer includes AlxGa1−xAs (0≤x≤1) having at least two or more types of different compositions.

13. The surface emitting device according to claim 1, wherein
the first reflective layer or the second reflective layer includes a material having a less thermal resistance and a wider stopband width than a reflective layer formed by stacking InP and AlxGayIn1−x−y As (0≤x, y≤1).

14. The surface emitting device according to claim 1, wherein the first reflective layer or the second reflective layer is formed by stacking at least two or more types of dielectric materials.

15. The surface emitting device according to claim 1, wherein the first reflective layer or the second reflective layer comprises a lens-type reflective layer.

16. The surface emitting device according to claim 1, wherein
the first reflective layer or the second reflective layer is stacked on the first semiconductor layer, the third semiconductor layer, or the fourth semiconductor layer with at least one foreign substrate being interposed therebetween, the foreign substrate being selected from GaAs, Si, GaN, AlN, BN, and SiC.

17. The surface emitting device according to claim 1, further comprising:
a first electrode electrically coupled to the first reflective layer or a clad layer; and
a second electrode electrically coupled to the third semiconductor layer.
